(19) United States
(12) Patent Application Publication
(10) Pub. No.: US 2007/0054505 A1
(43) Pub. Date: Mar. 8, 2007

(54) PECVD processes for silicon dioxide films

(76) Inventors: George A. Antonelli, Portland, OR (US); Mandayam A. Sriram, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/219,249

(22) Filed: Sep. 2, 2005

(51) Int. Cl. H01L 21/31; H01L 21/469

(52) U.S. Cl. 438/789

(57) ABSTRACT

Embodiments of the present invention provide PECVD (plasma enhanced chemical vapor deposition) processes that produce uniform, dense SiO₂ (silicon dioxide) films having a high purity that are suitable for use in IC device fabrication. Advantageously, these processes do not require the use of a DC bias or dual frequency RF power and can use some of the same precursors used to make low-k ILD films.

### BACKGROUND OF THE INVENTION

1. Field of the Invention

The present invention relates to the production of integrated circuit (IC) device structures and the deposition of silicon dioxide (SiO₂) using plasma enhanced chemical vapor deposition (PECVD).

2. Background Information

The integration of low-k films or layers into semiconductor devices has presented challenges associated with issues of film porosity, mechanical integrity, and intercomponent reactivity. Low-k films having dielectric constants of about 3 to about 2.7 are typical of current processes. The production of integrated circuit device structures can necessitate placing a silicon dioxide (SiO₂) film or layer, or capping layer on the surface of low-k (low dielectric constant) ILD (inter-layer dielectric) films. Typically, the deposition of low-k ILD films occurs in a different PECVD (plasma enhanced chemical vapor deposition) tool and or reaction chamber than the PECVD tool or reaction chamber used to deposit a high quality SiO₂ films or layers.

An example of a PECVD process typically used for creating a high quality SiO₂ films on semiconductor substrates is shown in FIG. 1. As can be seen from FIG. 1, silane (SiH₄) and nitrous oxide (N₂O) are reacted in a plasma to deposit a SiO₂ film or layer. In this example, a RF power is applied that has both a high frequency (13.5 MHz) and a low frequency component (typically, about 1 to about 400 KHz) and an optional DC bias.

Transfer of a semiconductor substrate (a wafer) between process chambers increases the expense involved in IC fabrication due in part to the decrease in fabrication rate and the increase in device failure rate. Further, a transfer between process chambers involving a vacuum break is potentially detrimental to the integrity of the interface between a SiO₂ layer and a low-k ILD layer.

Additionally, the SiO₂ PECVD processes that use either a DC bias or a low frequency RF component in the plasma may damage the dielectric properties of the low-k layer.

### BRIEF DESCRIPTION OF THE FIGURES

FIG. 1 provides a process that can be used to deposit a silicon dioxide film by PECVD on a semiconductor substrate.

FIG. 2 shows a process according to the invention that can be used to deposit a silicon dioxide film by PECVD on a semiconductor substrate.

FIG. 3 graphically presents the dependence of deposition rate of a PECVD SiO₂ film on the oxygen gas precursor flow rate (sccm) and also its dependence on RF power (Watts) in a process according to an embodiment of the present invention.

FIG. 4 shows a Fourier transform infrared (FTIR) spectrum of a SiO₂ film deposited using a process according to the present invention.

FIGS. 5A and 5B provide comparisons of density (FIG. 5A) and HF etch rate (FIG. 5B) between SiO₂ films produced by three different PECVD processes.

FIG. 6 shows the results of dielectric constant measurements by Mercury probe of a low-k ILD film on which SiO₂ films had been deposited by two different PECVD processes and subsequently removed.

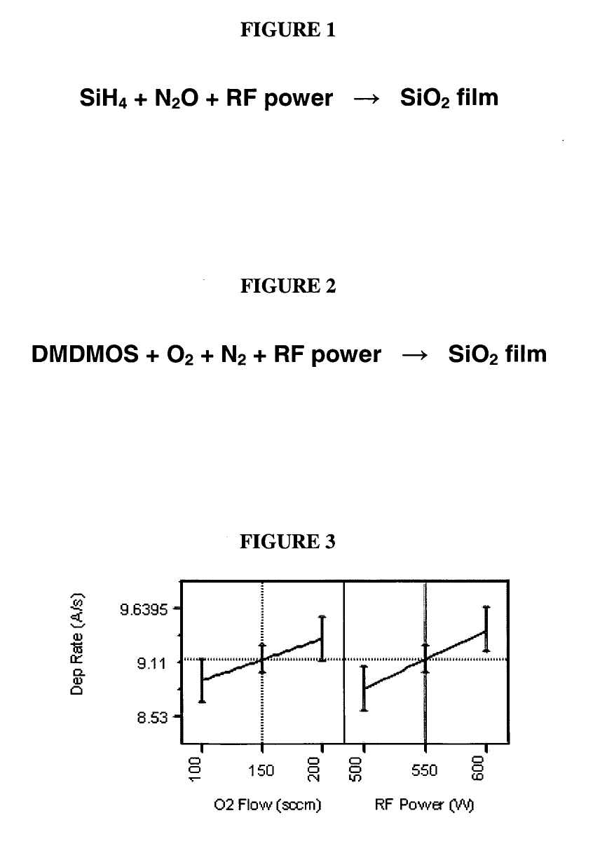

### DETAILED DESCRIPTION OF THE INVENTION

Embodiments of the present invention provide PECVD (plasma enhanced chemical vapor deposition) processes that are compatible with other integrated circuit fabrication processes and that produce SiO₂ films suitable for use in integrated circuit devices. The terms, chip, integrated circuit, monolithic device, semiconductor device, and microelectronic device, are often used interchangeably in this field. The SiO₂ films produced are suitable, for example, as capping layers and can be formed over low-k dielectric films. Typically, low-k films are considered to be any film with a dielectric constant smaller than that of SiO₂ which has a dielectric constant of about 4.0. Preferably the low-k film has a dielectric constant of less than about 3.5 and more preferably, less than about 3.0. Low-k films can be, for example, boron, phosphorous, or carbon doped silicon oxides. Carbon-doped silicon oxides can also be referred to as carbon-doped oxides (CDOs) and organo-silicate glasses (OSGs). Capping layers formed over low-k ILDs are typically a fraction of an ILD layer thick and currently about 5 to about 50 nm would be normal thickness for a capping layer, although other layer thicknesses can be created.

Referring now to FIG. 2, a PECVD process according to an embodiment of the present invention in which a SiO₂ film is formed from a low-k precursor is illustrated schematically. Precursor molecules are capable of supplying silicon atoms to the reactive process that forms the SiO₂ film. In the process shown in FIG. 2, a SiO₂ film is deposited using a mixture of a silicon-organic precursor, in this case dimethyldimethoxysilane (DMDMOS, (CH₃O)₂Si(CH₃)₂), oxygen gas (O₂) (an oxidant), and nitrogen gas (N₂) (a carrier gas). The precursor DMDMOS can also be used to create low-k ILD films, such as for example, Applied Material's Black Diamond, ASM's Aurora ULK, and Novellus Systems' Coral films. Silicon-organic precursors are vaporizable molecules that contain silicon, hydrogen, and carbon. Optionally, the silicon-organic precursor may also contain oxygen. Typical silicon-organic precursors for low-k dielectric films include, for example, octamethylcyclotetrasiloxane (OMCTS, ((CH₃)₂SiO)₄), dimethylmethoxysilane (DEMS, (CH₃)₂(CH₃O)SiH), diethyldiethoxysilane (DEDEOS, (C₂H₅O)₂Si(C₂H₅)₂), dimethyldimethoxysilane (DEDMOS), trimethyltrimethoxysilane, methyl phenyl dimethoxysilane, diphenyl dimethoxysilane, tetramethylcyclotetrasiloxane (TMCTS, (CH₃(H)SiO)₄), trimethylsilane (3MS, (CH₃)₃SiH), and tetramethylsilane (4MS, (CH₃)₄Si). The nitrogen gas can be used as a background (carrier) gas to dilute the precursor and oxidant gas flows. Other carrier gases could also be used in this process instead of or in addition to the N₂ gas, such as for example, Neon (Ne) gas or Argon (Ar) gas. This process could also be performed with oxidants other than O₂ or in addition to O₂, such as for example, nitrous oxide gas (N₂O), ozone (O₃), water (H₂O), or carbon dioxide gas (CO₂). Additionally, vaporizable liquid weak oxidizers, such as for example, methyl, ethyl, and isopropyl alcohol, in vapor form, may be used. Advantageously, these alcohols also tend to stabilize the plasma.

Advantageously, the process shown in FIG. 2 can be run using an RF power having a single frequency component. Exemplary RF frequencies include frequencies that are harmonics of 13.5 MHz, such as for example, 13.5 MHz, 27 MHz, 40.5 MHz, and 54 MHz. The RF power can be set low enough so that nitrogen gas is not ionized, that is, undetectably low amounts of N₂⁺ ions are formed. For example, the RF power can be about 300 to about 1000 Watts, preferably about 400 to about 850 Watts, and preferably about 500 to about 700 Watts. The concentration, or lack thereof, of N₂⁺ ions can be verified from the distinct spectral footprint left by N₂⁺ using optical emission spectroscopy (OES). Advantageously, nitrogen incorporation into a SiO₂ film produced by this low energy nitrogen plasma is negligible. Further, the process illustrated in FIG. 2 can be run without the use of a DC bias, thus eliminating a damage mechanism for underlying components, such as, for example, a low-k ILD film.

In the process generally illustrated in FIG. 2 for forming a high quality SiO₂ film, the pressure in the reaction chamber is generally about 0.5 to about 3 Torr, preferably about 1 to about 2 Torr. The ratio of the amount of precursor, e.g., DMDMOS, to oxidant, e.g., O₂, is about 1:7 (pressure of precursor gas to pressure of O₂ gas) and the ratio of the amount of precursor to N₂ is about 1:67 (pressure of precursor gas to pressure of N₂ gas) for the reaction to form SiO₂. In general, these reactant ratios can range from about 1:5 to about 1:15 for pressure of precursor to pressure of oxidant and about 1:25 to about 1:150 for pressure of precursor to pressure of N₂. Typical gas flow rates were about 20-50 sccm (standard cubic centimeters per minute) for precursor (DMDMOS), about 50-250 sccm for oxidant (O₂), and about 1000-4000 sccm for carrier gas (N₂).

Further, embodiments of the present invention provide PECVD processes that allow for a range of deposition rates for the resulting high quality SiO₂ films. FIG. 3 graphically presents the dependence of the rate of SiO₂ deposition (in Angstroms per second) on the rate of flow of O₂ gas (in sccm) into the process chamber and on RF power (in Watts). As can be seen from FIG. 3, a SiO₂ deposition rate can be obtained that is about 1 nm/s or less. This low deposition rate enables great control over the thickness of the resulting film and thus the use of this SiO₂ film as a capping layer. The thickness as shown in FIG. 3 was measured using a spectroscopic ellipsometer, and the data was confirmed by X-ray reflectivity measurements. Data was collected on a 10-50 nm film deposited on silicon using conditions as described above.

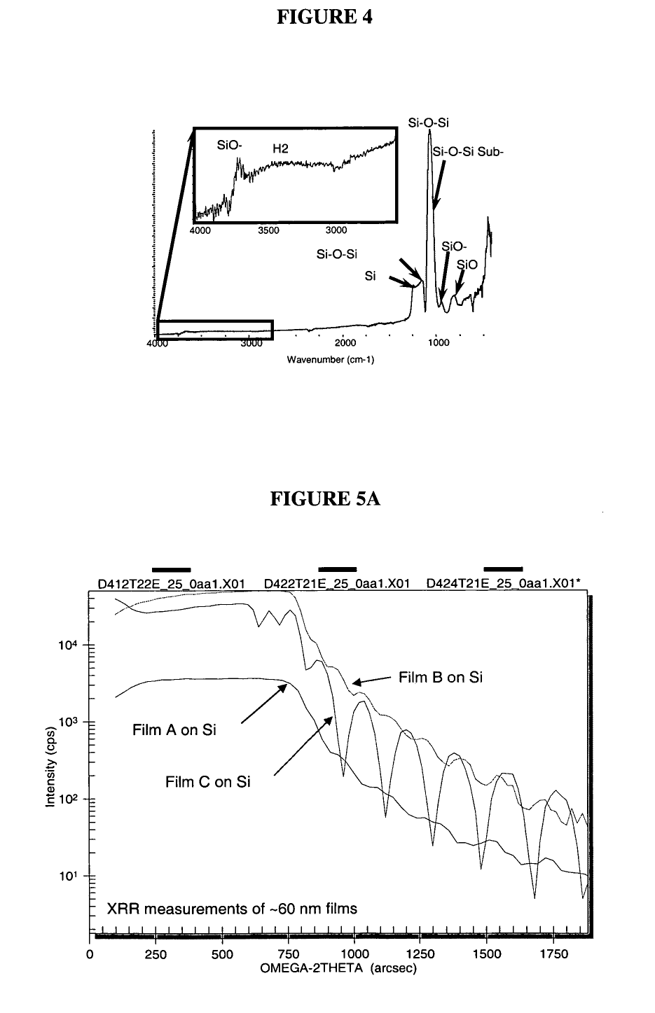

Referring now to FIG. 4, a Fourier transform infrared (FTIR) spectrum of an embodiment of the invention is presented. The FTIR spectrum in FIG. 4 shows labeled peaks from an as-deposited PECVD SiO₂ film. As can be seen from the FTIR spectrum, peaks can be assigned to Si—O interactions and peaks from trace carbon, such as for example, signature peaks from —CH₃ end groups, which are a component of DMDMOS-based low-k ILD films, and are discernable at about 1270 cm⁻¹, are not seen. Similarly, peaks attributable to trace amounts of nitrogen in the SiO₂ film are not discernable in the spectrum, such as for example, no discernable peak was found at 3380 cm⁻¹ which would correspond to a N—H bond, and no peak was discerned at 885 cm⁻¹ which would correspond to a Si—N bond. FTIR data was collected on an Accent QS-3300ME in-fab 300 mm FTIR system in transmission mode on a 150-300 nm film deposited on silicon using process conditions as described above. Lack of nitrogen incorporation into the film was further verified with secondary ion mass spectrometry (SIMS).

Embodiments of the invention provide SiO₂ films having a carbon content of less than about 0.1% and a nitrogen content of less than about 0.1%. Further, SiO₂ films are provided that have a Si to O ratio of about 1:2 plus or minus 10% (i.e., a Si to O ratio of about 0.9:2 to about 1.1:2) by weight.

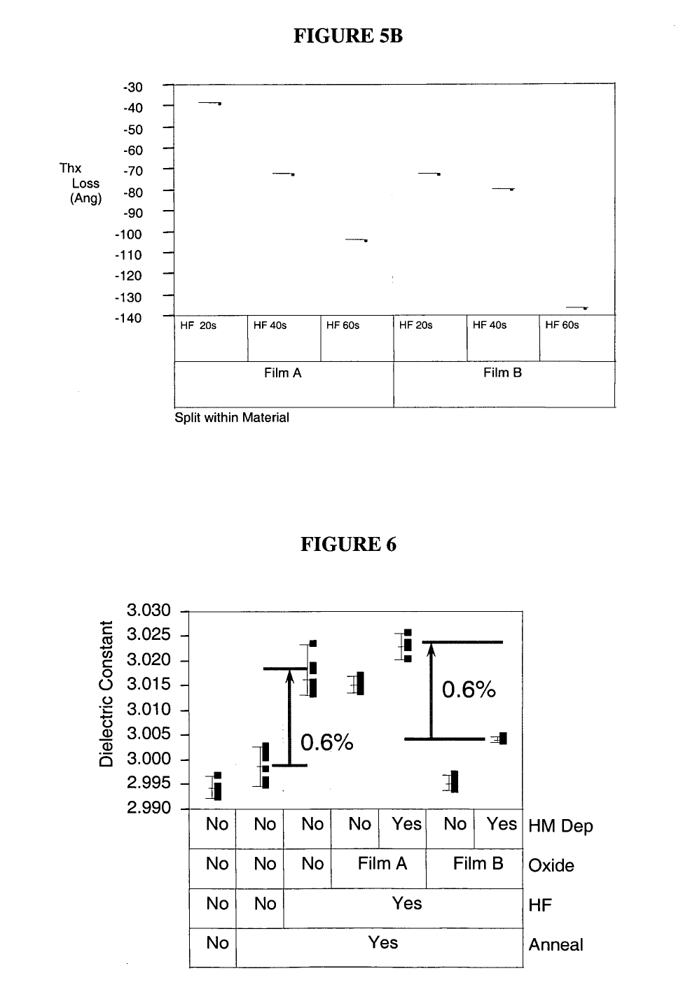

Density and etch rate are factors used to determine the quality of SiO₂ films. In general, a SiO₂ film should have a density that is as close as possible to the density of bulk SiO₂, about 2.2 g/cm³. Measurements of density and etch rate for three films of similar thickness, a target of about 60 nm, deposited on a silicon wafer: an exemplary PECVD SiO₂ embodiment (labeled Film A), a reference high quality PECVD SiO₂ film (created from SiH₄ and N₂O precursors) (labeled Film B), and a low density low-k ILD film (a DMDMOS-based CDO low-k film deposited on the same platform and in the same chamber as the SiO₂ capping layer) (labeled Film C) having a nominal density of 1.35 g/cm³, are provided in FIGS. 5A and 5B, respectively. The magnitude of the Kiessig thickness fringes in an XRR (X-ray reflectometry) measurement is indicative of the density of the film as compared to Si. FIG. 5A shows the results of XRR measurements for Films A-C that yielded densities for Films A and B of 1.8 g/cm³. FIG. 5B presents results obtained from 200:1 HF (water:HF by weight:weight) etch rate measurements for Films A and B. The XRR measurements were made on a Bede 300 mm X-ray system on films of about 60 nm thickness deposited directly on a silicon substrate. In FIG. 5B, the etch rates for the total etched thickness of Film A and Film B in 60 seconds in a 200:1 HF solution are very similar, again demonstrating the similarity between these two films. It can also be seen from FIG. 5B the etch rate for Film A is more linear than that of Film B, indicating that Film A possesses more through-film structural or compositional uniformity.

Further evidence of compatibility for the PECVD SiO₂ films of the invention with a process requiring a SiO₂ capping layer on a low-k ILD, was provided by dielectric constant measurements of the low-k ILD film subsequent to the deposition of a PECVD SiO₂ capping layer. FIG. 6 presents dielectric constant measurements by Mercury probe of a low-k ILD film (a DMDMOS based low-k film, Film C above) on which capping layers comprised of Film A and Film B (previously described) had been deposited and subsequently removed. Measurements were made on an SSM Mercury Probe system operating at a frequency of 100 kHz with a voltage range of −40 to −110 V. The low-k ILD film thickness was about 500 nm. The oxide cap was removed prior to testing. The process of deposition and subsequent removal of the SiO₂ layers (Film A and Film B) consisted of: (1) PECVD SiO₂ deposition (oxide); (2) hard mask (HM) film deposition; (3) 200:1 HF dip; and (4) anneal. The wafers containing the films were pulled at several points in the deposition and removal process to assess the impact of each step. It should be noted, however, that the data reflected in FIG. 6 also reflects the effects of a hard mask deposition and a 200:1 HF dip. An about 0.6% increase in dielectric constant was found that correlates with the deposition of Film A. Although this increase in dielectric constant is small enough to be considered essentially negligible, it should be noted that, in FIG. 6, Film A was half the thickness of Film B and HF has a considerable effect on the low-k ILD in absence of the SiO₂ capping layer. Thus, the observed increase in dielectric constant may be more related to increased exposure of the low-k ILD to HF for the thinner Film A sample than the deposition process for Film A.

Film thickness uniformity can be quantified by the standard deviation or range of the thickness of film as measured at many sites across the wafer. A useful measurement is provided by the equation: 100*(thickness range)/(mean thickness), wherein the thickness range is defined as the difference between the maximum and minimum value in a set of measurements. It is a metric used to evaluate the largest level of variation observed in a set of experimental data. Processes of the present invention can provide films that have a uniformity of at least less than 10%. The processes discussed herein provided thickness uniformities ranging from about 5 to about 7%.

In general, the processes of the present invention can be run using a PECVD platform having a PECVD reaction chamber, having a generator, a low pressure control, and a proper gas delivery system for the low-k precursor and the other reactant gases selected. The processes described were run on a 300 mm ASM Eagle platform. However, tools such as, for example, 200 and 300 mm PECVD tools from Novellus Systems, Inc., and Applied Materials, Inc. could also be used.

We claim:

1. A method of depositing a silicon dioxide film by plasma enhanced chemical vapor deposition (PECVD) comprising:
providing a mixture comprising a silicon-organic precursor, an oxidant, and a carrier gas;
depositing a silicon dioxide film on a surface using the mixture of the silicon-organic precursor, the oxidant, and the carrier gas by plasma enhanced chemical deposition;
wherein plasma enhanced chemical deposition is accomplished by using an RF power that has not more than one frequency component and by not applying a DC bias to the surface on which the film is deposited.

2. The method of claim 1 wherein the silicon-organic precursor is selected from the group consisting of octamethylcyclotetrasiloxane, dimethylmethoxysilane, dimethyldimethoxysilane, diethyldiethoxysilane, dimethyldimethoxysilane, trimethyltrimethoxysilane, methyl phenyl dimethoxysilane, diphenyl dimethoxysilane, tetramethylcyclotetrasiloxane, trimethylsilane, and tetramethylsilane.

3. The method of claim 2 wherein the silicon-organic precursor is dimethyldimethoxysilane.

4. The method of claim 1 wherein the oxidant is selected from the group consisting of oxygen, ozone, water, nitrous oxide, and carbon dioxide.

5. The method of claim 1 wherein the oxidant is a vaporizable alcohol.

6. The method of claim 1 wherein the carrier gas selected from the group consisting of N₂, Ar, Ne, and mixtures thereof.

7. The method of claim 1 wherein the oxidant is oxygen and the carrier gas is N₂.

8. The method of claim 1 wherein the RF frequency is a harmonic of 13.5 MHz.

9. The method of claim 8 wherein the RF frequency is 27 MHz.

10. The method of claim 2 wherein the rate of deposition of the SiO₂ film is about 1 nm per second or less.

11. The method of claim 2 wherein the resulting silicon dioxide film has a thickness uniformity of less than about 10%.

12. The method of claim 2 wherein the resulting silicon dioxide film has a carbon content of less than about 0.1% and a nitrogen content of less than about 0.1%.

13. The method of claim 2 wherein the resulting silicon dioxide film has a silicon to oxygen ratio of about 0.9:2 to about 1.1:2 by weight.

14. The method of claim 1 wherein the resulting silicon dioxide film has a thickness of about 5 nm to about 50 nm.

15. A method of depositing a silicon dioxide film by plasma enhanced chemical vapor deposition (PECVD) comprising:
providing a semiconductor substrate surface having a low-k film thereon;
depositing a SiO₂ film on at least part of the low-k film;
wherein depositing the SiO₂ film comprises: providing a mixture comprising a low-k precursor that was used to form the low-k film, an oxidant, and a carrier gas, and depositing a film using the mixture on a surface of the low-k film by plasma enhanced chemical deposition;
wherein depositing the SiO₂ film occurs in the same reaction chamber in which the low-k film was deposited.

16. The method of claim 15 wherein the low-k precursor is selected from the group consisting of octamethylcyclotetrasiloxane, dimethylmethoxysilane, dimethyldimethoxysilane, diethyldiethoxysilane, dimethyldimethoxysilane, trimethyltrimethoxysilane, methyl phenyl dimethoxysilane, diphenyl dimethoxysilane, tetramethylcyclotetrasiloxane, trimethylsilane, and tetramethylsilane.

17. The method of claim 15 wherein the oxidant is selected from the group consisting of oxygen, ozone, water, nitrous oxide, and carbon dioxide.

18. The method of claim 15 wherein depositing the SiO₂ film is accomplished by using an RF power having not more than one frequency component.

19. The method of claim 15 wherein the carrier gas selected from the group consisting of N₂, Ar, Ne, and mixtures thereof.

20. The method of claim 19 wherein the RF frequency is a harmonic of 13.5 MHz

21. The method of claim 19 wherein the RF frequency is 27 MHz.

22. The method of claim 15 wherein the resulting silicon dioxide film has a carbon content of less than about 0.1% and a nitrogen content of less than about 0.1%.

23. The method of claim 15 wherein the resulting silicon dioxide film has a thickenss uniformity of less than about 10%.

24. The method of claim 15 wherein the resulting silicon dioxide film has a silicon to oxygen ratio of about 0.9:2 to about 1.1:2 by weight.

25. The method of claim 15 wherein the low-k film has a dielectric constant of less than about 3.5.

26. The method of claim 15 wherein the resulting silicon dioxide film has a thickness of about 5 nm to about 50 nm.
